(19) United States
(12) Patent Application Publication
(10) Pub. No.: US 2006/0051683 A1
(43) Pub. Date: Mar. 9, 2006

(54) Method of manufacturing mask for exposure, mask for exposure, and package body of mask for exposure

(75) Inventor: Yukihiro Sato, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/012,276

(22) Filed: Dec. 16, 2004

(30) Foreign Application Priority Data
Sep. 9, 2004 (JP) 2004-262511

(51) Int. Cl. G03C 5/00; G03F 1/00

(52) U.S. Cl. 430/5; 430/323; 430/324; 430/30

(57) ABSTRACT

There are provided a method of manufacturing a mask for exposure, which includes the step of patterning a light-shielding film formed on a quartz substrate to form a light-shielding pattern, and the step of directly measuring a step from the surface of the quartz substrate to the top surface of the light-shielding pattern to obtain the actual measurement value of the step.

### CROSS-REFERENCE TO RELATED APPLICATIONS

This application is based on and claims priority of Japanese Patent Application No. 2004-262511 filed on Sep. 9, 2004, the entire contents of which are incorporated herein by reference.

### BACKGROUND OF THE INVENTION

1. Field of the Invention

The present invention relates to a method of manufacturing a mask for exposure, a mask for exposure, and a package body of a mask for exposure.

2. Description of the Prior Art

In recent years, semiconductor devices have increasingly become further microfabrication, and the minimum dimension of a device pattern has reached as fine as 90 nm. To form such an extremely fine device pattern, it is necessary that not only light having short wavelength (193 nm) of an ArF laser or the like be used as exposure light but also the dimensions of a device pattern, which is obtained from an exposure pattern of a mask for exposure, be rigorously controlled in exposure process.

The mask for exposure has various types such as a mask where a light-shielding pattern is simply formed on a transparent substrate and a phase shift mask where the phase of exposure light is inverted only by n between adjacent light-shielding patterns to improve resolution. In any mask for exposure, the dimensions of a device pattern must be rigorously controlled in order to further carry out the microfabrication of device patterns.

Note that Patent Document 1 discloses technology to make the film thickness of a light-shielding film thin in order to increase the film thickness ratio of the phase shift film with respect to a light-shielding film, in a mask for exposure of Levenson type.

[Patent Document 1] Japanese Patent Laid-open No. 8-15850 publication

### SUMMARY OF THE INVENTION

It is an object of the present invention to provide a method of manufacturing a mask for exposure, a mask for exposure, and a package body of a mask for exposure, where the dimensional fluctuation of a device pattern can be easily guaranteed.

According to one aspect of the present invention, there is provided a method of manufacturing a mask for exposure, comprising the steps of: patterning a light-shielding film formed on a transparent substrate to form a light-shielding pattern; and directly measuring a step from the surface of the transparent substrate to the top surface of the light-shielding pattern to obtain the actual measurement value of the step.

The above-described measurement of step is not performed generally because it increases the number of processes and there is no need of such measurement. However, a simulation that the inventors of this application performed made it clear that the fluctuation of step affected the dimensional fluctuation of a device pattern. Thus, by obtaining the actual measurement value of step, the dimensional fluctuation of a device pattern can be guaranteed.

Although such a guarantee method is not specifically limited, it is preferable to perform the steps of: setting an allowable width to the dimensional fluctuation amount of a device pattern; providing a tolerance for the step to bring the dimensional fluctuation of the device pattern within the allowable width; and determining whether or not to proceed to the next manufacturing step depending on whether or not the difference between the actual measurement value of the step and the design film thickness of the light-shielding pattern falls into the tolerance.

With this configuration, it is possible to determine whether or not the dimensional fluctuation amount of the device pattern falls within the allowable width depending on whether or not the difference between the actual measurement value of the step and the design film thickness of the light-shielding pattern falls into the tolerance, and thus the dimensions of the device pattern can be guaranteed.

Further, it is preferable to set the above-described tolerance of the step corresponding to the design film thickness of the light-shielding film.

Furthermore, it is preferable that the step of providing the tolerance for the step be performed that a graph showing the relationship between the fluctuation amount of the step and the dimensional fluctuation amount of the device pattern is created, the fluctuation amount of the step is calculated referring to the graph such that the dimensional fluctuation amount of the device pattern falls into the allowable width, and the fluctuation amount is used as the tolerance.

Although a method of measuring the step is not limited, it is preferable to measure the step by using an AFM (Atomic Force Microscope) system or a contact type step measurement system.

When the contact type step measurement system is used, scanning of the transparent substrate between patterns by the probe of the system is difficult if the distance between adjacent light-shielding patterns is dense. Therefore, in this case, it is preferable that an isolated pattern be provided in a peripheral region of the transparent substrate, the isolated pattern and the transparent substrate near the pattern be scanned by the probe, and the measurement value is used as the above-described actual measurement value. With this method, the step of the isolated pattern can be easily measured even if the light-shielding pattern is formed in high density to deal with the microfabrication of device, so that the dimensional fluctuation of the device pattern can be controlled based on the step.

Further, according to another aspect of the present invention, there is provided a mask for exposure comprising: a transparent substrate; a light-shielding pattern formed in a device region on which the device pattern is projected, on the transparent substrate; and an isolated pattern formed in the peripheral region of the device region, on the transparent substrate.

Then, according to still another aspect of the present invention, there is provided a package body of a mask for exposure, comprising: a mask for exposure in which the light-shielding pattern is formed on the transparent substrate; and an inspection result card on which the actual measurement value from the surface of the transparent substrate to the top surface of the light-shielding pattern is written.

Since the actual measurement value written on the above-described inspection result card is obtained by directly measuring the step, the step can be guaranteed with good accuracy comparing to the case where the step is substituted by the design film thickness of a light-shielding film that is formed on the entire surface of a quartz substrate and leads to difficulty of actual measurement of the film thickness.

### BRIEF DESCRIPTION OF THE DRAWINGS

FIGS. 1A to 1D are sectional views for explaining a manufacturing method of a mask for exposure, which is generally performed in the embodiments of the present invention.

FIG. 2 is a sectional view of an etching chamber used in the embodiments of the present invention.

FIG. 3 is a configuration view of a stepper 6 which sets the mask for exposure that is fabricated in the embodiments of the present invention.

FIGS. 4A to 4D are process sectional views of a manufacturing process of a semiconductor device, which is performed by using the mask for exposure of the embodiments of the present invention.

FIG. 5 is a plan view of a model of the mask for exposure that was used in an optical intensity simulation of the embodiments of the present invention.

FIG. 6 is a graph obtained by simulating the influence to the line width of the device pattern with respect to change of the design film thickness of the light-shielding pattern, in the embodiments of the present invention.

FIG. 7 is a flowchart showing the manufacturing method of a mask for exposure according to a first embodiment of the present invention.

FIG. 8 is the sectional view of the mask for exposure fabricated in the first embodiment of the present invention.

FIG. 9 is a graph of line width fluctuation amount of device pattern to step fluctuation amount, which is used in the first embodiment of the present invention.

FIG. 10 is a plan view showing measurement points of step H of the mask for exposure in the first embodiment of the present invention.

FIG. 11 is a graph showing the actual measurement values of the step H, which was actually measured by an AFM system in the first embodiment of the present invention.

FIG. 12 is a sectional view when the step H is measured by a contact type step measurement system in a second embodiment of the present invention.

FIG. 13 is a plan view of a mask for exposure according to the second embodiment of the present invention.

FIG. 14 is a perspective view of a package body of a mask for exposure according to a third embodiment of the present invention.

### DESCRIPTION OF THE PREFERRED EMBODIMENTS

Best modes for implementing the present invention will be explained in detail with reference to the attached drawings hereinafter.

(1) Explanation of Preliminary Items

The preliminary items of the present invention will be described before explaining the embodiments of the present invention.

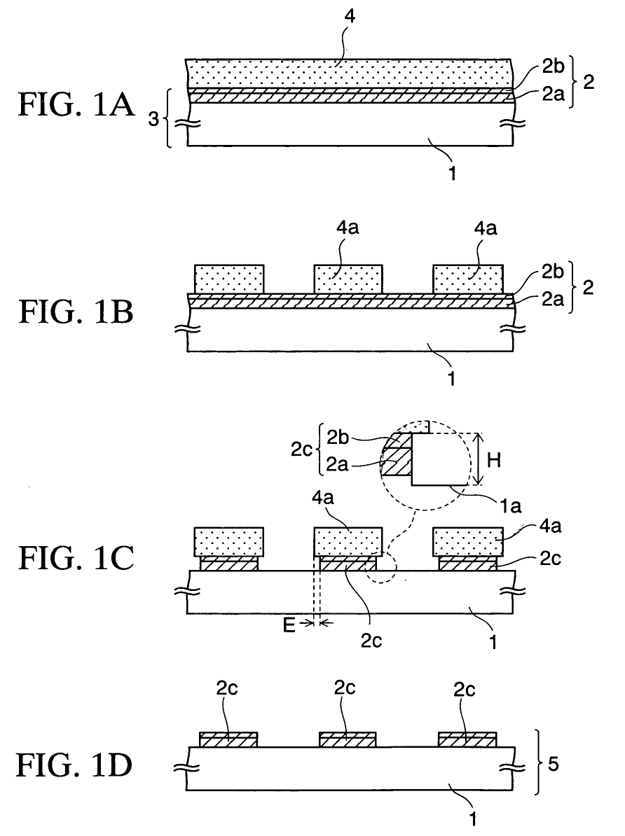

FIGS. 1A to 1D are in-process sectional views of a mask for exposure, which are generally performed.

First of all, description will be made for process until the sectional structure shown in FIG. 1A will be obtained.

A quartz substrate (transparent substrate) 1 is brought into a sputtering chamber (not shown) first, the quartz substrate 1 is mounted on a stage that is previously heated in the chamber, and the quartz substrate 1 is heated to a predetermined temperature. Then, after Ar (argon) is introduced into the sputtering chamber as sputtering gas, direct current voltage is applied between the stage and a Cr (chromium) target, and a chromium layer 2a is formed on the quartz substrate 1 at the thickness of about 73 nm by sputtering.

Subsequently, O₂ (oxygen) is supplied into the chamber to sputter the Cr target by the mixed gas of Ar and O₂. Accordingly, O₂ in the sputtering gas reacts with Cr of the target to generate chromium oxide in a gas phase, and thus a chromium oxide layer 2b is formed on the quartz substrate 1 at the thickness of about 30 nm. Such a sputtering method is called a reactive sputtering method.

Consequently, it results in formation of a light-shielding film 2 having the thickness of about 103 nm, which is made up of the chromium layer 2a and the chromium oxide layer 2b. The chromium oxide layer 2b that constitutes the light-shielding film 2 functions as an anti-reflection film that prevents the reflection of exposure light in the mask for exposure after it is completed.

Further, a material constituting the light-shielding film 2 is not limited to chromium and chromium oxide, but any material of metal, and oxide, nitride and oxynitride of the metal may constitute the light-shielding film 2.

The light-shielding film 2 and the quartz substrate 1 constitute blanks 3 in combination.

Subsequently, a positive chemically amplified resist as a photoresist 4 is coated on the light-shielding film 2 at the thickness of about 400 nm, and it is baked. Since the positive chemically amplified resist is superior in light transmittance due to a smaller doped amount of acid generator comparing to a non-chemically amplified resist, it is preferable for forming fine patterns. However, the non-chemically amplified resist may be used as the photoresist 4 for a device where microfabrication of pattern is not strictly required. In addition, a negative chemically amplified resist may be formed as the photoresist 4.

The foregoing process is done by a manufacturer of the blanks 3, and the thickness of the light-shielding film 2 of the blanks 3 that is currently supplied to the market is approximately the above-described 103 nm at the thinnest. And a manufacturer of semiconductor devices purchases the blanks 3 on which the photoresist 4 is coated as shown in FIG. 1A from the manufacturer of the blanks 3, and performs the following process to the blanks.

Firstly, as shown in FIG. 1B, after the photoresist 4 is exposed, PEB (Post Exposure Bake) is performed to the photoresist 4 to promote the generation of acid in the resist. Then, the photoresist 4 is developed into a resist pattern 4a.

Subsequently, as shown in FIG. 1C, the light-shielding film 2 is etched by plasma etching while the resist pattern 4a is used as a mask, and thus a light-shielding pattern 2c is formed.

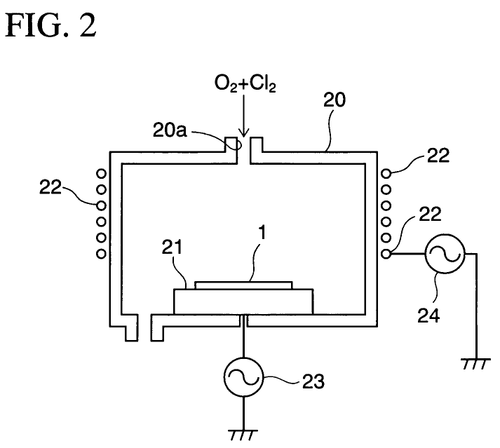

The plasma etching is performed by using an ICP (Inductively Coupled Plasma) etching chamber as shown in FIG. 2, for example. A lower electrode 21 on which the quartz substrate 1 is mounted is provided inside an etching chamber 20, and radio frequency electric power having the frequency of 13.56 MHz is applied to the lower electrode 21 by the first radio frequency power source 23. Further, a coil 22 for generating magnetic field is provided on the outer periphery of the chamber 20. Then, radio frequency electric power having the frequency of 2 MHz is applied to the coil 22 by the second radio frequency power source 24.

Further, a gas supply port 20a is provided on the top surface of the chamber 20, and the mixed gas of O₂ and Cl₂, which is the etching gas, is introduced from the gas supply port 20a into the chamber 20.

In such an etching chamber 20, plasma in etching atmosphere is pulled vertically toward the quartz substrate 1 by increasing the power of the radio frequency electric power applied to the lower electrode 21, and the anisotropy of etching can be enhanced.

Furthermore, the etching rate inside the chamber 20 is not uniform on the in-plane of the quartz substrate 1, the rate generally has different values near the center and the inner periphery of the quartz substrate 1. Accordingly, in the etching, etching time is set to the slowest etching time such that the entire film is rather over-etched. As a result, as shown inside a dotted circle of FIG. 1C, the surface 1a of the quartz substrate 1, which is exposed between the light-shielding films 2c, is slightly etched by the plasma. The etched amount is typically smaller than 10 nm.

Next, as shown in FIG. 1D, ashing is performed to the resist pattern 4a by oxygen to remove it. However, since the partial pattern 4a changed in quality by plasma etching is not removed by ashing, it is preferable to completely remove all resist pattern 4a by wet processing after the ashing.

Consequently, the fundamental structure of a mask for exposure 5 is completed.

Subsequently, process proceeds to the manufacturing process of the semiconductor device using the mask for exposure 5.

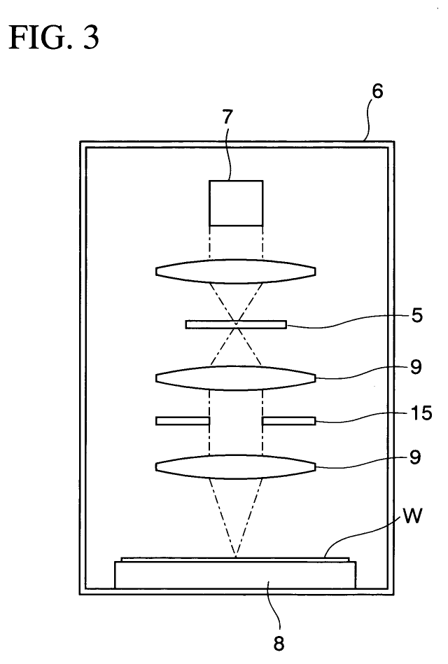

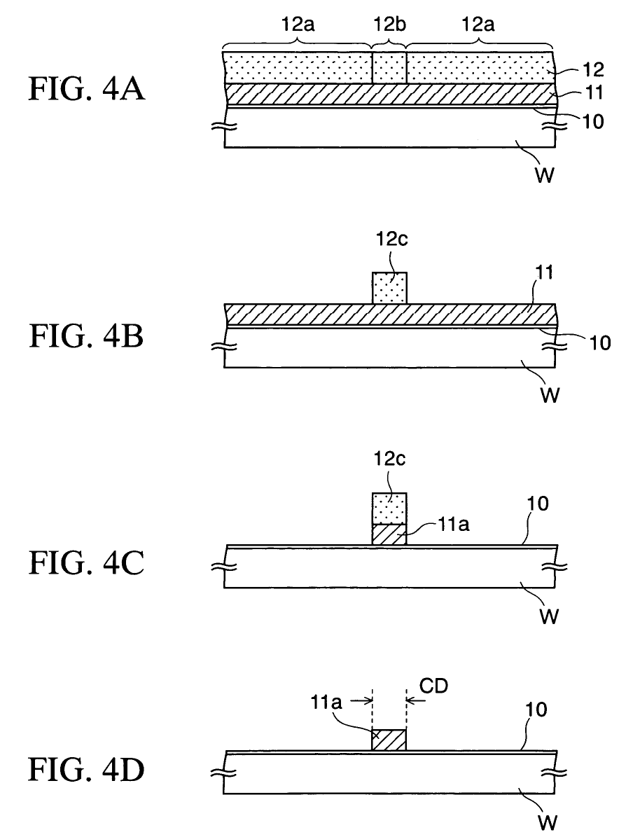

FIG. 3 is the configuration view of a stepper 6 in which the mask for exposure 5 is used, FIGS. 4A to 4D are process sectional views of photolithographic process using the stepper 6.

First, as shown in FIG. 3, the mask for exposure 5 is set in the stepper 6, the exposure light such as ArF laser light emitted from a light source 7 is allowed to pass through the mask for exposure 5, and the light exposes a light-shielding pattern on a silicon wafer W mounted on a stage 8. The exposed pattern is a scale-down pattern of the light-shielding pattern 2c by a predetermined reduction magnification, which is the reduction magnification of ¼, for example. Further, the luminous flux of the exposure light is shaped by an illumination aperture 15.

As shown in FIG. 4A, a thermal oxidation film 10 being a gate insulating film and a polysilicon layer 11 being a gate electrode are sequentially formed on the silicon wafer W, and a photoresist 12 for patterning the polysilicon layer 11 is additionally formed thereon.

Then, as a result of the exposure described above, the photoresist 12 is exposed and an exposed area 12a and a non-exposed area 12b are formed on the photoresist 12.

Thereafter, as shown in FIG. 4B, the exposed areas 12a are removed by developing the photoresist 12, and a resist pattern 12c made up of the non-exposed area 12b is formed on the polysilicon layer 11.

Next, as shown in FIG. 4C, by etching the polysilicon layer 11 while the resist pattern 12c is used as an etching mask, a gate electrode made of polysilicon is formed as a device pattern 11a.

In the foregoing, the gate electrode was cited as an example of the device pattern 11a, but the device pattern is not limited to this. The device pattern defined in this specification is a film to which patterning was performed by using the resist pattern as an etching mask. As well as the gate electrode, an interlayer insulating film on which grooves or holes are formed, a metal wiring, or the like corresponds to such film.

Next, as shown in FIG. 4D, the resist pattern 12c is removed by oxygen ashing and wet processing. Then, processing proceeds to cleaning process and its detail will be omitted.

In the above-described manufacturing method of a mask for exposure, the etching anisotropy of the light-shielding film 2 is enhanced by applying radio frequency electric power having a large power to the lower electrode 21 in the etching chamber 20.

However, if the power of the above-described radio frequency electric power is increased too high in order to enhance the etching anisotropy, plasma in the etching atmosphere has high kinetic energy, and the plasma causes film thickness reduction of the resist pattern 4a. In the worst case, the resist pattern are lost before the etching of the light-shielding film 2 is completed.

To solve such problem, the power of the radio frequency electric power applied to the lower electrode 21 is turned down to reduce the damage suffered by the resist pattern 4a.

However, this increases the horizontal kinetic component with respect to the quartz substrate 1 out of the kinetic components of the plasma in the etching atmosphere, which results in smaller etching anisotropy. Thus, as shown in FIG. 1C, the side of the light-shielding pattern 2c goes backward significantly. Such amount E of backward movement is also called an etching bias.

When the etching bias E is large, the planar shape of the light-shielding pattern 2c does not follow that of the resist pattern 4a, which makes it difficult to obtain the light-shielding pattern 2c of a designed shape and the dimensional accuracy of the light-shielding pattern 2c deteriorates.

Such fact leads to consideration of making the thickness of the light-shielding film 2 thinner than the current thickness of 103 nm, as a method of leaving the resist pattern 4a even after etching and reducing the etching bias E. With this method, since etching is completed in a short time due to the thin thickness of light-shielding film 2 even if the radio frequency electric power to be applied to the lower electrode 21 is increased to reduce the etching bias E, the resist pattern 4a will not be lost during etching.

However, a phenomenon that has not been discovered so far occurs when the thickness of the light-shielding film 2 is made thinner, and thus there is a fear that new affair will occur.

The inventors of this application conducted the following optical intensity simulation from this viewpoint.

In this optical intensity simulation, exposure light was allowed to virtually transmit the mask for exposure 5, and the line width (dimension) CD of the device pattern 11a (refer to FIG. 4D), which was obtained from image of the light-shielding pattern 2c, was calculated. Then, models 1 to 3 shown in Table 1 were assumed as the models of the mask for exposure 5, in the optical intensity simulation.

TABLE 1

| | Thickness t, | Thickness t, | |
|---|---|---|---|
| | refractive | refractive | |
| | index n, and | index n, and | Design film |
| | absorption | absorption | thickness T₀ |
| | coefficient k | coefficient k | of light- |
| | of chromium | of chromium | shielding |
| | layer 2a | oxide layer 2b | pattern 2c |
| Sample 1 | t = 73 nm, | t = 30 nm, | T₀ = 103 nm |
| | n = 1.477, | n = 1.939, | |
| | k = 1.762 | k = 0.941 | |
| Sample 2 | t = 55 nm, | t = 18 nm, | T₀ = 73 nm |
| | n = 1.477, | n = 1.965, | |
| | k = 1.762 | k = 1.201 | |
| Sample 3 | t = 39 nm, | t = 20 nm, | T₀ = 59 nm |
| | n = 1.477, | n = 1.871, | |
| | k = 1.762 | k = 1.130 | |

As shown in Table 1, the design film thickness of the light-shielding pattern 2c was changed in each model (1 to 3).

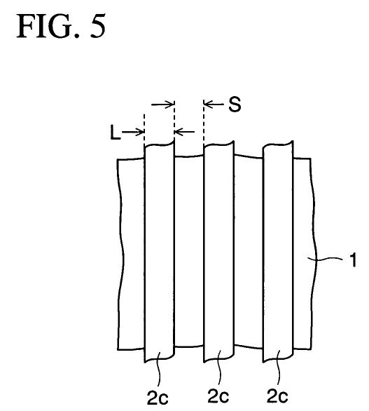

Further, values calculated from the actual measurement values of the transmittance and reflectance of each model (1 to 3) were used as the optical constant (refractive index n, and absorption coefficient k) of each model (1 to 3). Then, as shown in FIG. 5, line (L) and space (S) where both are 560 nm was employed as the planar shape of the light-shielding pattern 2c. Further, exposure wavelength of 193 nm (ArF), numerical aperture (NA) of 0.7, and illumination aperture ((a) of 0.7 were used as exposure conditions.

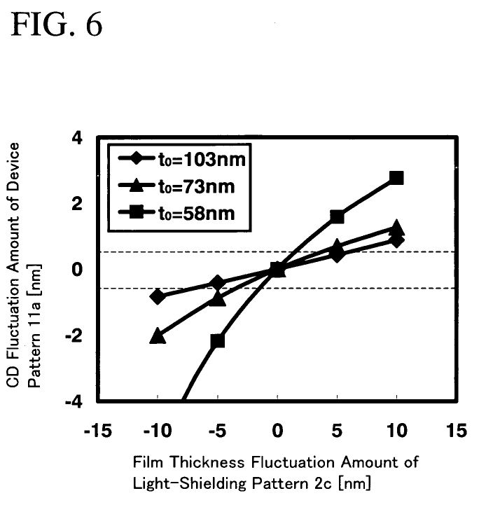

Then, the influence to the line width CD of the device pattern 11a was simulated with respect to change of the design film thickness of the above-described light-shielding pattern 2c. The result shown in FIG. 6 was obtained.

The axis of abscissas in FIG. 6 shows fluctuation amount where the film thickness of the light-shielding pattern 2c of each model (1 to 3) shown in Table 1 was increased/decreased from its design film thickness, and reference codes + and − respectively corresponds to increase and decrease of the film thickness. On the other hand, the axis of ordinate shows the fluctuation amount of the line width CD of the device pattern, where the fluctuation amount thereof was obtained from the projected image of the light-shielding pattern 2c with respect to change of the film thickness of the light-shielding pattern 2c.

From the result of FIG. 6, the occurrence of two phenomena is understood.

The first phenomenon is that the fluctuation of the line width of the device pattern 11a, which was obtained from the projected image of the light-shielding pattern 2c, depends on the film thickness fluctuation of the light-shielding pattern 2c, and this phenomenon occurs regardless of the design film thickness (t₀=103 nm, 73 nm, 58 nm) of the light-shielding pattern 2c. Note that the design film thickness t₀ is the film thickness of the light-shielding film 2 guaranteed by the blanks manufacturer. On the other hand, in the case where the light-shielding film 2 is formed in a semiconductor factory without depending on the blanks manufacturer, the design film thickness t₀ is that of the light-shielding film 2 indirectly guaranteed by a deposition rate or the like.

The second phenomenon is that as the film thickness of the light-shielding pattern 2c is made thinner, the slope of the graph of FIG. 6 becomes steeper, and in other word the film thickness fluctuation of the light-shielding pattern 2c largely influences the line width fluctuation of the device pattern 11a.

Although this simulation employed the film thickness of the light-shielding pattern 2c as a parameter, the surface 1a of the quartz substrate 1 is slightly etched by plasma etching in the actual mask for exposure 5, as shown in the dotted circle of FIG. 1C. Therefore, the above-described first and second phenomena also occur by the fluctuation of a step H, where the step H combines the etched amount of the surface 1a of quartz substrate and the film thickness of the light-shielding pattern 2c.

Based on the newly found phenomena, the inventors of this application have reached the concept of the following embodiments of the present invention.

(2) First Embodiment

Next, the manufacturing method of a mask for exposure according to the first embodiment of the present invention will be explained.

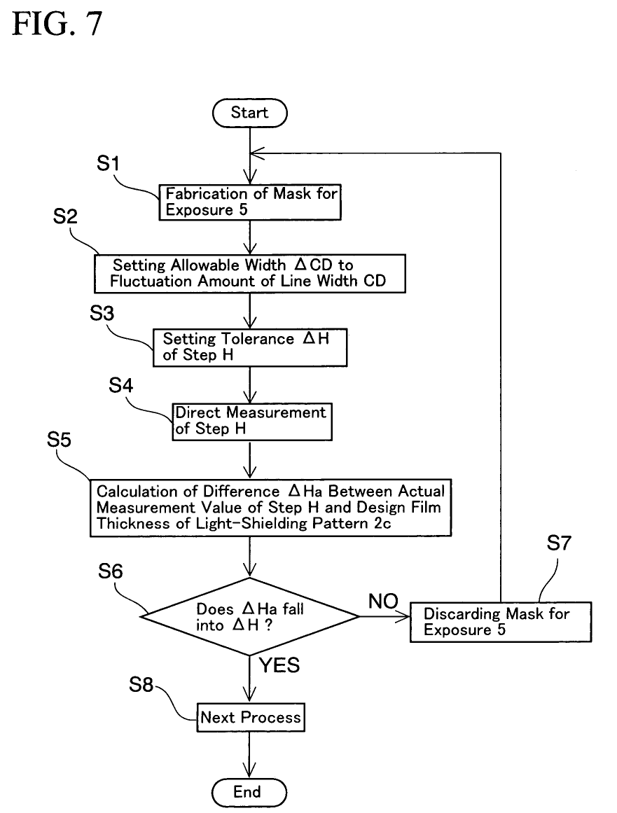

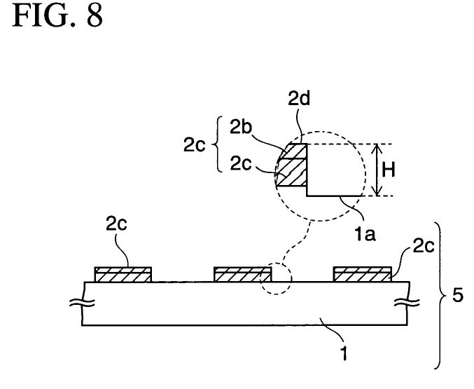

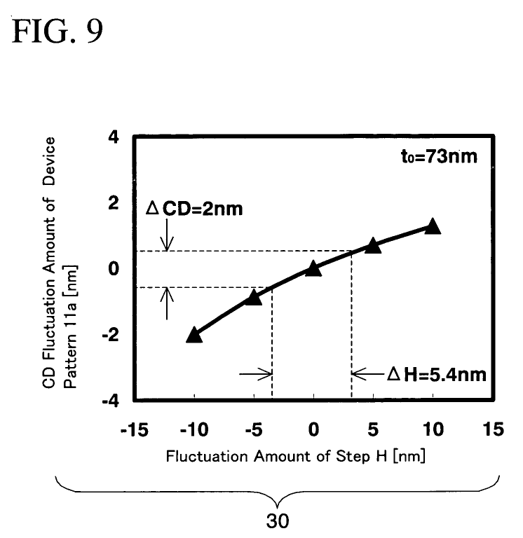

FIG. 7 is the flowchart showing the manufacturing method of a mask for exposure according to this embodiment, and FIG. 8 is the sectional view of the mask for exposure formed by this embodiment. In FIG. 8, reference numerals same as the ones used in FIG. 1D are attached to elements that was already described in FIG. 1D, and their explanation will be omitted. Further, FIG. 9 is the graph of the line width fluctuation amount (CD) of device pattern to the step fluctuation amount, which is used in this embodiment.

The steps S1 to S8 shown in FIG. 7 are performed not only to a mask for exposure for test but also to all masks for exposure 5.

On step S1, the mask for exposure 5 shown in FIG. 8 is fabricated by following the described FIGS. 1A to 1D. In this embodiment, a substrate having the planar size of 152.4 mm×152.4 mm and the thickness of 6.35 mm is used as the quartz substrate 1 that constitutes the mask for exposure 5.

Further, the film thickness of the light-shielding pattern 2c is not particularly limited, and may be the film thickness of approximately the current 103 nm or thicker. However, it is preferable to set the film thickness to 50 nm or more and 110 nm or less. The reason why the lower limit of the film thickness is set to 50 nm is that the minimum thickness by which the film thickness uniformity or the like of the light-shielding pattern 2c is maintained is approximately 50 nm. In addition, the reason why the upper limit of the film thickness is set to 110 nm is that the etching bias E (refer to FIG. 1C) becomes large and the dimensional accuracy of the light-shielding pattern 2c deteriorates when the film thickness is thicker than 103 nm.

In this embodiment, 73 nm thinner than 103 nm is employed as the design film thickness of the light-shielding pattern 2c in order to make the etching bias E small and thus improve the dimensional accuracy of the light-shielding pattern 2c.

However, the design film thickness is the film thickness of the light-shielding film 2 (refer to FIG. 1A) guaranteed by the blanks manufacturer, and it usually has an error of several nm within a substrate plane. The reason why the error occurs is that the light-shielding film 2 is formed on the entire surface of the quartz substrate 1 and the surface of the quartz substrate 1, which is a reference point of film thickness, is covered with the light-shielding film 2 when the blanks 3 is shipped from the manufacturer, and there is no means for directly measuring the design film thickness. Therefore, the above-described film thickness error of the light-shielding film 2 is generated when the blanks 3 is manufactured not in the blanks manufacturer but in the semiconductor factory.

Further, in performing plasma etching when the light-shielding pattern 2c (refer to FIG. 8) is formed, the surface 1a of the quartz substrate 1 is etched as described, so that the step H from the surface 1a to the top surface 2d of the light-shielding pattern 2c becomes slightly thicker than the thickness of the light-shielding pattern 2c.

Then, process proceeds to step S2 of FIG. 7, and an allowable width ΔCD is set to the fluctuation amount of the line width CD of the device pattern 11a (refer to FIG. 4D). The allowable width ΔCD is an index that shows how much the line width CD is allowed to fluctuate from the design line width, and a method of setting the allowable width is not particularly limited and it may be set by an appropriate method corresponding to the design rule, the type, or the process of a device.

In this embodiment, the upper limit and the lower limit of the above-described allowable width ΔCD are set to +1 nm and −1 nm, respectively, and thus ΔCD is set to 2 nm (=+1 nm-(−1 nm)).

Next, process proceeds to step S3, referring to the graph 30 of the line width (CD) fluctuation amount of device pattern to the step fluctuation amount shown in FIG. 9. Note that the graph 30 is prepared in plural numbers for each design film thickness t₀ of the light-shielding pattern 2c. FIG. 9 shows only the graph for t₀=73 nm. Then, on this step, a graph equivalent to 73 nm that is the design film thickness of the light-shielding pattern 2c is referred to out of a plurality of graphs 30.

The graph 30 may be created based on the simulation same as FIG. 6 described above, or may be created upon conducting an actual experiment. Further, since the graph 30 employs the fluctuation amount of the step H as the axis of abscissas, the accuracy of the line width (CD) on the axis of ordinate has been improved comparing to FIG. 6 where only the film thickness fluctuation amount of the light-shielding pattern 2c is used without taking etching of the substrate in consideration.

In addition, as described in FIG. 6, the slope of the graph becomes steep as the thickness of the light-shielding pattern 2c becomes thinner.

Then, referring to the graph 30, a tolerance ΔH is provided for the step H such that the line width fluctuation of the device pattern 11a falls into the allowable width ΔCD. Since the graph 30 is in monotone increase, the upper limit and the lower limit of the tolerance ΔH are values onto the axis of abscissas in the graph 30, in which correspond to the upper limit and the lower limit of the allowable width ΔCD, respectively. In this case, since the upper limit and the lower limit of the allowable width ΔCD are +1 nm and −1 nm respectively, the upper limit and the lower limit of the tolerance ΔH are +2.7 nm and −2.7 nm respectively, and it results in ΔH=5.4 nm (=+2.7 nm-(−2.7 nm)).

Furthermore, it is preferable that the tolerance ΔH be set corresponding to the design film thickness t₀.

Next, process proceeds to step S4 of FIG. 7, where the mask for exposure 5 shown in FIG. 8 is brought into the AFM (Atomic Force Microscope) system, the step H from the surface 1a of the quartz substrate 1 to the top surface 2d of the light-shielding pattern 2c is directly measured, and the actual measurement value of the step H is thus obtained.

Unlike the solid light-shielding film 2 of the blanks, which is formed on an entire surface, the surface 1a of the quartz substrate 1, which becomes the reference point of the step H, is exposed between the light-shielding patterns 2c, and thus the step H can be directly and accurately measured.

Note that the contact type step measurement system is also used other than the AFM system as the measurement system for obtaining the actual measurement value of the step H.

The measurement point of the step H and its amount are not particularly limited. However, the step H is in different values depending on the position on the substrate due to the non-uniformity of the film thickness of the light-shielding pattern 2c and etching in forming the pattern, and statistical reliability of the measurement value is low when the step H is measured at only one point.

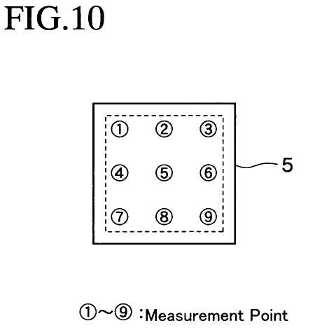

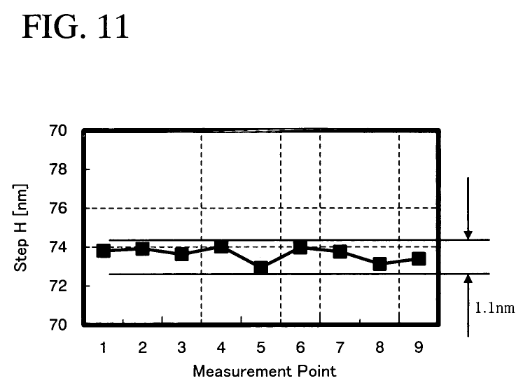

Therefore, as shown in the plan view of FIG. 10, measurement is performed on in-plane nine points of the mask for exposure 5 in this embodiment. FIG. 11 is the graph showing the actual measurement values of the step H, that were actually measured by the AFM system, and the uniformity of the step H is about 1.1 nm in this example.

Subsequently, process proceeds to step S5 of FIG. 7, where the difference ΔHa between the actual measurement values of the step H and the design film thickness (73 nm) of the light-shielding pattern 2c is calculated on all of the above-described in-plane nine points.

Then, process proceeds to step S6 of FIG. 7, and whether or not the difference ΔHa calculated on step S5 falls into the tolerance ΔH (refer to FIG. 9), which was set on step S3, is determined on all of the above-described in-plane nine points. If the difference ΔHa does not fall into the tolerance ΔH at least on one point of the in-plane nine points (NO) as a result of the determination, the line width CD of the device pattern fluctuates exceeding the allowable width ΔCD on the point, and there is a fear that the device will be defective.

In such a case, process does not proceeds to the next manufacturing process, but proceeds to step S7 and the mask for exposure 5 is discarded. Then, process returns to step S1 and the mask for exposure 5 is fabricated again.

On the other hand, when the difference ΔHa falls into the tolerance ΔH on all of the in-plane nine points (YES), the fluctuation width of the line width CD of the device pattern can be brought into the allowable width ΔCD and a device having characteristic as designed can be fabricated. Consequently, it is determined to proceed to the next manufacturing process, and process proceeds to step S8.

In the example of FIG. 11, since the maximum value of the difference ΔHa is about 1.0 nm that falls into the tolerance of 5.4 nm, process can proceed to step S8.

On step S8, the line width of the light-shielding pattern 2c, for example, is measured to confirm if the line width is formed as designed.

This concludes primary steps of the manufacturing method of the mask for exposure 5 according to this embodiment.

According to this embodiment described above, the step H, which is not usually measured because of the reason of increased steps of process, is measured, and whether or not the difference ΔHa between the actual measurement value and the design film thickness of the light-shielding pattern 2c falls into the tolerance ΔH of the step H, which is defined by the graph 30, is determined. Then, based on the result of the determination, whether or not the fluctuation of the line width CD of the device pattern 11a, which is obtained from the projected image of the light-shielding pattern 2c, falls into the allowable width ΔCD is determined.

In the graph 30, the thinner the design film thickness t₀ of the light-shielding pattern 2c, the more steep the slope of the graph becomes, and thus the tolerance ΔH of the step H defined by the allowable width ΔCD becomes narrower as the design film thickness t₀ of the light-shielding pattern 2c becomes thinner, so that it is required to strictly control the step H.

In the current light-shielding pattern 2c having the thickness of 103 nm, the film thickness fluctuation amount of the light-shielding film guaranteed by the blanks manufacturer is about ±5 nm on the in-plane, but it is actually smaller than the value and is about ±2 nm. However, it is predicted that the fluctuation amount of the step H on the current mask 5 be about ±5 nm when the etching amount (about 1 to 3 nm) of the substrate 1 caused by the plasma etching is also taken in consideration.

Then, the axis of abscissas of the graph explained in FIG. 6 is allowed to represent the above-described fluctuation amount of the step H, the tolerance ΔH of the step H should be ±5 nm in order to bring the allowable width ΔCD of the fluctuation amount of the line width CD within the range of ±1 nm similar to this embodiment. Accordingly, in the current light-shielding pattern 2c having the thickness of 103 nm, the fluctuation amount of the line width CD automatically falls into the allowable width ΔCD, and there is little need to actually measure the step as in this embodiment.

However, in the case of employing thinner film thickness (for example, the film thickness of 58 nm) than the current one as the design film thickness of the light-shielding pattern 2c, the tolerance ΔH of the step H needs to be ±1.3 nm based on FIG. 6, which is more strict than the film thickness fluctuation amount of the light-shielding film guaranteed by the blanks manufacturer.

For this reason, when employing the light-shielding pattern 2c having a thinner film thickness than the current one, the mask for exposure 5, in which the line width fluctuation of the device pattern is guaranteed into the allowable width CD, can be provided by applying this embodiment. Particularly, it is possible to improve the dimensional accuracy of fine device pattern in most advanced photolithography.

(3) Second Embodiment

Next, the mask for exposure according to the second embodiment will be explained.

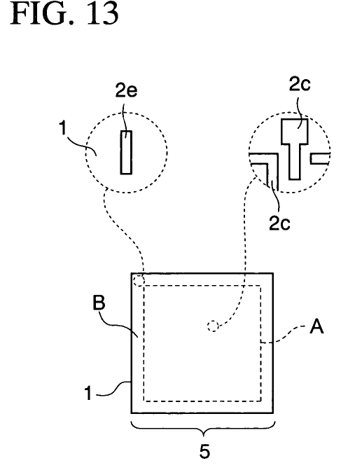

FIG. 13 is the plan view of the mask for exposure according to this embodiment.

In the first embodiment, the actual measurement value of the step H was obtained using the AFM system on step S7 of FIG. 7. On the contrary, description in this embodiment will be made for the mask for exposure 5 that is preferable for measuring the step H by the contact type step measurement system.

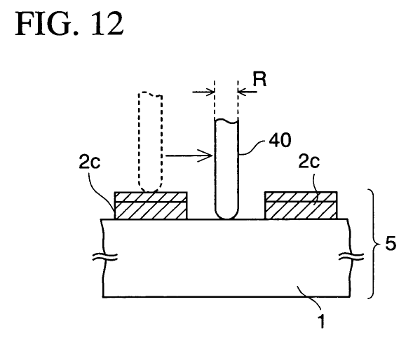

FIG. 12 is the sectional view in the case of measuring the step H by the contact type step measurement system.

In this system, as shown in the drawing, the tip of a probe 40 is allowed to come into contact with the surface of the quartz substrate 1 or the light-shielding pattern 2c, the probe 40 is made to scan in one direction under this condition, and the step on the surface is calculated based on the moved amount of the probe 40 in vertical directions corresponding to the irregularity of a scanned surface.

However, if the gap between adjacent light-shielding patterns 2c is smaller than the diameter R of the probe 40, the probe 40 cannot go between the light-shielding patterns 2c, and there is a fear that the system cannot measure the step.

Particularly, since the gap between the light-shielding patterns 2c is narrower in the mask for exposure 5 that corresponds to fine design rule, accurate measurement of the step H is difficult due to the above-described reason.

Consequently, the mask for exposure 5 having the plan view shown in FIG. 13 is fabricated in this embodiment.

The mask for exposure 5 is roughly divided two-dimensionally into device region A on which a pattern for device is projected, and peripheral region B around region A. Then, the above-described light-shielding pattern 2c is formed on device region A, and an isolated pattern 2e is formed on peripheral region B.

The isolated pattern 2e is formed simultaneously with the light-shielding pattern 2c by the same process, and is provided in an isolated manner on peripheral region B.

On step S7 of FIG. 7, the step H between the top surface of the isolated pattern 2e and the surface of the quartz substrate 1 is measured using the contact type step measurement system.

With this mask, the tip pf the probe 40 come into contact with the surface of the quartz substrate 1 without fail when the probe 40 of the step measurement system is allowed to scan, so that the step H can be measured more accurately comparing to the case of directly measuring the light-shielding pattern 2c on device region A.

(4) Third Embodiment

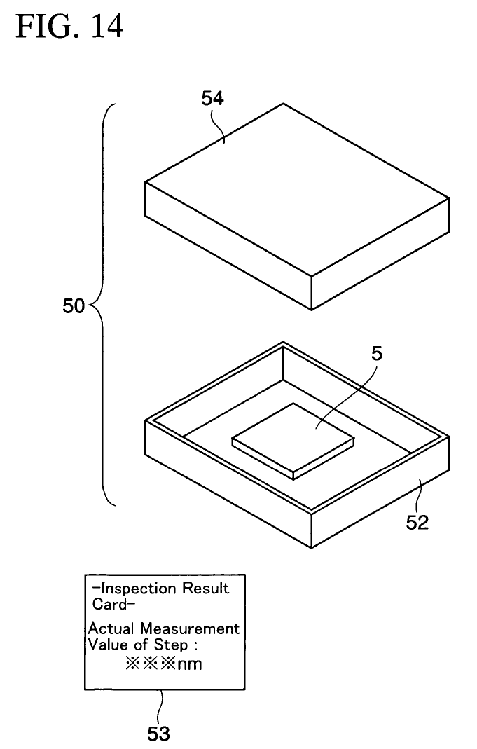

FIG. 14 is the perspective view of the package body of a mask for exposure according to this embodiment.

The package body 50 for a mask for exposure is made up of a plastic package box 52 that houses the mask for exposure 5 fabricated in the first and second embodiments, and a lid 54 is placed on the package box 52 in the case of transportation.

Further, an inspection result card 53 is attached to the package body 50, on which the actual measurement value of the step H from the surface of the quartz substrate 1 to the top surface of the light-shielding pattern 2c is written, as described in the first and second embodiments. Since the actual measurement value is the one measured on step S4 of FIG. 7 and the value was obtained by directly measuring the step H, the step H can be guaranteed with good accuracy comparing to the case where the step H is substituted by the design film thickness of the light-shielding film 2 guaranteed by the blanks manufacturer.

The embodiments of the present invention have been explained in detail above, but the present invention is not limited to the embodiments. Although description has been made in the embodiments for the mask for exposure 5 on which the light-shielding pattern 2c was simply provided on the quartz substrate 1, the present invention can be also applied for a phase shift mask.

According to the present invention, since the step from the surface of the transparent substrate to the top surface of the light-shielding pattern is directly measured to obtain the actual measurement value of the step, the dimensional fluctuation of the device pattern can be guaranteed based on the actual measurement value.

Further, by providing the tolerance for the above-described step and finding on whether or not the difference between the actual measurement value of the step and the design film thickness of the light-shielding pattern falls into the tolerance, it is possible to determine whether or not the dimensional fluctuation of the device pattern falls into the allowable width.

What is claimed is:

1. A method of manufacturing a mask for exposure, comprising the steps of:
patterning a light-shielding film formed on a transparent substrate to form a light-shielding pattern; and
measuring a step from the surface of said transparent substrate to the top surface of said light-shielding pattern to obtain the actual measurement value of the step.

2. The method of manufacturing a mask for exposure according to claim 1, said method comprising the steps of:
setting an allowable width to the dimensional fluctuation amount of a device pattern;
providing a tolerance for said step to bring the dimensional fluctuation of said device pattern within said allowable width; and
determining whether or not to proceed to the next manufacturing step depending on whether or not the difference between the actual measurement value of said step and the design film thickness of said light-shielding pattern falls into said tolerance.

3. The method of manufacturing a mask for exposure according to claim 2, wherein
the tolerance of said step is set corresponding to the design film thickness of said light-shielding pattern.

4. The method of manufacturing a mask for exposure according to claim 2, wherein
the step of providing the tolerance for said step is performed by creating a graph showing the relationship between the fluctuation amount of said step and the dimensional fluctuation amount of said device pattern, then calculating the fluctuation amount of said step referring to the graph so as to bring the dimensional fluctuation amount of said device pattern within said allowable width, and thus using the fluctuation amount as said tolerance.

5. The method of manufacturing a mask for exposure according to claim 4, wherein
said graph is created for each set film thickness of said light-shielding film.

6. The method of manufacturing a mask for exposure according to claim 1, wherein
the step of obtaining the actual measurement value of said step is performed by using any one of an AFM (Atomic Force Microscope) system and a contact type step measurement system.

7. The method of manufacturing a mask for exposure according to claim 1, wherein
on the step of forming said light-shielding pattern, an isolated pattern is formed on the peripheral region of a device region on said transparent substrate at the same time when said light-shielding pattern is formed on said device region subject to projection of the device pattern on said transparent substrate, and
on the step of obtaining the actual measurement value of said step, a step from the surface of said transparent substrate to the top surface of said isolated pattern, which has been measured by a contact type step measurement system, is employed as the actual measurement value.

8. The method of manufacturing a mask for exposure according to claim 1, wherein
the step of forming said light-shielding pattern is performed by forming a resist pattern on said light-shielding film and then performing plasma etching to said light-shielding film using the resist pattern as a mask, and
the step of obtaining the actual measurement value of said step is performed by employing the sum of the etched amount of said transparent substrate, which has been etched by said plasma etching, and the film thickness of said light-shielding pattern as said step.

9. The method of manufacturing a mask for exposure according to claim 1, wherein
any material selected from the group consisting of metal, and oxide, nitride and oxynitride of the metal is employed as a material that constitutes said light-shielding film.

10. The method of manufacturing a mask for exposure according to claim 9, wherein
chromium is employed as said metal.

11. The method of manufacturing a mask for exposure according to claim 1, wherein
the thickness of said light-shielding film is at a range of 50 nm to 110 nm.

12. A mask for exposure, comprising:
a transparent substrate;
a light-shielding pattern formed in a device region on which a device pattern is projected, on said transparent substrate; and
an isolated pattern formed in the peripheral region of said device region, on said transparent substrate.

13. A package body of a mask for exposure, comprising:
a mask for exposure in which the light-shielding pattern is formed on a transparent substrate; and
an inspection result card on which the actual measurement value of a step from the surface of said transparent substrate to the top surface of said light-shielding pattern is written.

14. The package body of a mask for exposure according to claim 13, wherein
said step is the sum of the film thickness of said light-shielding pattern and the etched amount of said transparent substrate, which has been etched when forming said light-shielding pattern by the patterning due to plasma etching.

15. The package body of a mask for exposure according to claim 14, wherein
said etched amount is smaller than 10 nm.
